(19) United States
(12) Patent Application Publication
(10) Pub. No.: US 2006/0275995 A1
(43) Pub. Date: Dec. 7, 2006

(54) Semiconductor integrated circuit device and design method thereof

(75) Inventor: Hiroshi Furuta, Kanagawa (JP)

Correspondence Address: FOLEY AND LARDNER LLP;SUITE 500, 3000 K STREET NW, WASHINGTON, DC, 20007, US

(73) Assignee: NEC Electronics Corporation

(21) Appl. No.: 11/437,699

(22) Filed: May 22, 2006

(30) Foreign Application Priority Data
Jun. 1, 2005 (JP) 2005-161433

(51) Int. Cl. H01L 29/94; H01L 21/20

(52) U.S. Cl. 438/396; 257/296

(57) ABSTRACT

A semiconductor integrated circuit device which is formed on an area comprises a first storage node which is formed on a first area having a first conductive type of the area, the first storage node having a first level, a second storage node which is formed on a second area having second conductive type of the area, the second storage node having a second level opposite to the first level and a well boundary which is sandwiched between the first area and the second area, wherein the second storage node has two diagonal lines, thereby, the first area having a first part sandwiched between the diagonal lines extended from the second storage node through the well boundary, and a second part which is the other part of the first part, wherein the first storage node is placed outside a region between the extended lines of two diagonal lines extending from the second storage node to the well boundary direction, and wherein the second storage node is placed outside a region between the extended lines of two diagonal lines extending from the first storage node to the well boundary direction.

### BACKGROUND OF THE INVENTION

1. Field of the Invention

The present invention relates to a semiconductor integrated circuit device and the design method thereof, and more particularly to a semiconductor integrated circuit device having a CMIS circuit and design method thereof.

2. Description of the Related Art

Recently the miniaturization of semiconductor integrated circuits is rapidly progressing, and as this progresses power supply voltage is dropping. In this situation soft error problems are becoming serious.

A soft error is also called a “single-event upset: SEU”, and refers to a phenomena where the data held in such a memory cell as an SRAM is inverted. A soft error is generated by the influence of alpha particle generated by radioactive impurities and radiation, such as cosmic ray neutrons, which reach from the outer universe to the ground. In particular the stored charge quantity decreases because of miniaturization, so an inversion of data easily occurs, and resistance to soft errors drops. Conventionally soft error countermeasures have been taken mainly for memory cells, but soft error countermeasures are becoming necessary also for logic circuits, such as a flip-flop circuit (hereafter F/F circuit) and a latch circuit, having a function to store (hold) data.

Now a soft error which generates in a conventional general latch circuit will be described. FIG. 10 shows a configuration of a conventional general latch circuit. As FIG. 10 shows, the latch circuit is comprised of a CMIS (Complementary Metal-Insulator Semiconductor) inverter 901 and CMIS inverter 902, which have MISFETs (Metal-Insulator Semiconductor Field-Effect Transistors). The output of the CMIS inverter 901 is input to the CMIS inverter 902, and the output of the CMIS inverter 902 is input to the CMIS inverter 901, so as to output data the opposite from each other and to stably hold data.

FIG. 11 is a cross-sectional view depicting a conventional general CMIS circuit. This is a configuration example of the CMIS inverters 901 and 902 in FIG. 10. This CMIS circuit is comprised of an NMISFET N910, which is formed in the P-well region 931 on the semiconductor substrate 930, and a PMISFET P920, which is formed in the N-well region 932, and P-well region 931 and the N-well region 932 are separated by the separation insulation film 933.

In the NMISFET N910, the gate electrode 911 is formed on the P-well region 931 via insulation film (not illustrated), and the storage node diffusion layer 912 and the power supply diffusion layer 913 are formed in the P-well regions 931 on both sides of the gate electrode 911. The storage node diffusion layer 912 is an N-type diffusion layer, and holds and outputs data as a drain of the NMISFET. The power supply diffusion layer 913 is an N-type diffusion layer, and is connected to a ground potential as the source of the NMISFET.

Just like the NMISFET N910, in the PMISFET P920 the gate electrode 921 is formed on the N-well region 932 via an insulation film (not illustrated), and the storage node diffusion layer 922 and the power supply diffusion layer 923 are formed in the N-well regions 932 on both sides of the gate electrode 921. For example, the storage node diffusion layer 922 is a P-type diffusion layer, and holds and outputs data as the drain of the PMISFET. The power supply diffusion layer 923 is a P-type diffusion layer, and is connected to the power supply potential of the source of the PMISFET.

For example, if radiation comes in from the outside to the storage node diffusion layer 912, electron-hole pairs are generated in a portion of the P-well region 931 where the radiation passed. Then the generated electrons are collected in the storage node diffusion layer 912, and when the electrons exceed the threshold, the data being held and output is inverted. In the NMISFET, if “H level (data 1)” is stored, the electrons are collected by the mechanism of drift and funneling and diffusion, and the data is inverted to “L level (data 0)”.

In the same way, if radiation comes in from the outside to the storage node diffusion layer 922, electron-hole pairs are generated in a portion of the N-well region 932 where the radiation passed. Then the generated holes are collected in the storage node diffusion layer 922 and when the holes exceed the threshold, the data being held and output is inverted. In the PMISFET, if “L level” is stored, the holes are collected by the mechanism of drift and funneling and diffusion, and the data is inverted to “H level”.

In the case of the latch circuit in FIG. 10, the CMIS inverters 901 and 902 hold logic information that is the opposite of each other, so the node diffusion layer of the NMISFET of one inverter of the CMIS inverters 901 and 902 and the node diffusion layer of the PMISFET of the other inverter hold logic information (logic level) that is the opposite from each other. Therefore the probability of a soft error to occur in this latch circuit is highest when electrons are collected in the storage node diffusion layer of a NMISFET storing “H level”, and at the same time holes are collected in the storage node diffusion layer of a PMISFET storing “L level”.

It is known that conventional soft error countermeasures for a logic circuit are, for example, disclosed in Tanay Karnik, et al, “Selective Node Engineering for Chip-level Soft Error Rate Improvement”, 2002 Symposium On VLSI Circuits, Digest of Technical Papers, pp. 204-205, and in Japanese Unexamined Patent Application Publication No. 2003-273709. In Tanay Karnik, et al, “Selective Node Engineering for Chip-level Soft Error Rate Improvement”, 2002 Symposium On VLSI Circuits, Digest of Technical Papers, pp. 204-205, the inversion of data is suppressed by adding a capacitor to the storage node of the F/F circuit, and in Japanese Unexamined Patent Application Publication No. 2003-273709, the inversion of data is suppressed by adding a new circuit to the holding node. In the case of Tanay Karnik, et al, “Selective Node Engineering for Chip-level Soft Error Rate Improvement”, 2002 Symposium On VLSI Circuits, Digest of Technical Papers, pp. 204-205 and Japanese Unexamined Patent Application Publication No. 2003-273709, the circuit scale increases because of the attached capacitor and added circuit, which causes an access problem including an increase in the layout area and a delay in operation speed.

Methods for preventing a soft error without adding circuits is disclosed in, T. Calin, et al, “Topology-Related Upset Mechanisms in Design Hardened Storage Cells”, Radiation and Its Effects on Components and Systems, RADECS97, Fourth European Conference, Sep. 15-19, 1997, and in Japanese Unexamined Patent Application Publication No. 9-330986. T. Calin, et al, “Topology-Related Upset Mechanisms in Design Hardened Storage Cells”, Radiation and Its Effects on Components and Systems, RADECS97, Fourth European Conference, Sep. 15-19, 1997 focuses on the placement of the diffusion layer of the MISFET, where the influence of the diffusion layer and the substrate (well) potential on a soft error is considered.

In Japanese Unexamined Patent Application Publication No. 9-330986, the shape of the diffusion layer of the MISFET, constituting the storage (holding) node, is improved, so as to suppress the charge collection of electron-hole pairs generated by radiation. In Japanese Unexamined Patent Application Publication No. 9-330986, however, fabrication dispersion occurs because the diffusion layer is bent in a complex way. Bending the diffusion layer also increases the area of the diffusion layer, so depending on the radiation which passes through, more electron-hole pairs may be collected.

In the soft error of SRAM cells, the subject of NMISFET (electron collection) has been receiving attention, as seen in F. Ootsuka, et al, “A Novel 0.20 μm Full CMOS SRAM Cell Using Stacked Cross Couple with Enhanced Soft Error Immunity”, IEEE IEDM98 (IEDM: International Electron Devices Meeting) 1998, pp. 205-208. It is shown in F. Ootsuka, et al, “A Novel 0.20 μm Full CMOS SRAM Cell Using Stacked Cross Couple with Enhanced Soft Error Immunity”, IEEE IEDM98 (IEDM: International Electron Devices Meeting) 1998, pp. 205-208 that the region of the NMISFET constituting the SRAM, that is the diagonal line length d of the P-well, is related to the SER (Soft Error Rate). According to FIG. 1 of F. Ootsuka, et al, “A Novel 0.20 μm Full CMOS SRAM Cell Using Stacked Cross Couple with Enhanced Soft Error Immunity”, IEEE IEDM98 (IEDM: International Electron Devices Meeting) 1998, pp. 205-208, the SER worsens as the node diffusion layer becomes larger if the voltage of the memory cells is the same.

Lately is has been reported that soft errors, due to PMISFET (hole collection), will increase in the future, as seen in Yukiya Kawakami et al, “Investigation of Soft Error Rate Including Multi-Bit Upset in Advanced SRAM Using Neutron Irradiation Test and 3-D Mixed-mode Device Simulation”, IEEE IEDM04, 2004, pp. 945-948. In FIG. 6 of Yukiya Kawakami et al, “Investigation of Soft Error Rate Including Multi-Bit Upset in Advanced SRAM Using Neutron Irradiation Test and 3-D Mixed-mode Device Simulation”, IEEE IEDM04, 2004, pp. 945-948, the simulation result shows that the radio of components due to the PMISFET in an entire SER increases as the voltage of SRAM decreases. This becomes more conspicuous as miniaturization advances and the size of the node diffusion layer decreases. However, in conventional SRAM cells, the placement of both PMOSFET and NMOSFET node diffusion layers is not decided considering the collection of charges (electrons, holes) generated by radiation, but the placement and shape of a diffusion layer are decided based on the aspect of the constraints in cell size, the improvement of yield (processing accuracy) and circuit operation. Particularly for the diffusion layer of PMOSFET, the collection of charges is not considered.

On the other hand, SOI (Silicon On Insulator) devices are known as a highly expected technology in the aspect of soft error countermeasures and in the improvement of MISFET characteristics. FIG. 12 is a perspective cross-sectional view depicting the configuration of a conventional MISFET with a general SOI structure. For example, the insulation film 951 is formed on the semiconductor substrate 950, the drain diffusion layer 953 and the source diffusion layer 954 are formed on this insulation film 951, and the gate electrode 952 is formed on the channel region 955 between the drain diffusion layer 953 and the source diffusion layer 954 via the insulation film (not illustrated).

In the case of an MISFET with an SOI structure, as shown in FIG. 12, because of a structure where a well region does not exist under the drain diffusion layer (storage node diffusion layer) 953 and because the layer is thin even if a well region exists, compared with a regular substrate, the quantity of electrons and holes generated by radiation and collected in the drain diffusion layer 953 (collected charge quantity) is low. Therefore in the case of an SOI device, the soft error rate improves.

However an SOI device has the problem of losing information because of the parasitic bipolar effect of radiation, as shown in Hideyuki Iwata et al, “Numerical Analysis of Alpha-Particle-Inducted Soft Errors in SOI MOS Devices”, IEEE Transactions On Electron Devices, Vol. 39, No. 5, May 1992, pp. 1184-1190. This problem is generated when radiation (ions) penetrate the source, channel and drain, as shown in FIG. 12(a), or when radiation penetrates the channel region toward the channel region stretching direction as shown in FIG. 12(b). Therefore the soft error countermeasures by an SOI device are limited.

In this way, soft error countermeasures are demanded for logic circuits, and not only for NMISFET but also soft error countermeasures for PMISFET are necessary. However in the case of a conventional semiconductor integrated circuit device, a new circuit is added or the shape of the diffusion layer becomes complicated to prevent a soft error, so it is difficult to suppress the generation of soft errors with a simple configuration in a semiconductor integrated circuit device having a CMIS circuit.

### SUMMARY OF THE INVENTION

A semiconductor integrated circuit device according to the present invention is a semiconductor integrated circuit device which is formed on an area comprises a first storage node which is formed on a first area having a first conductive type of the area, the first storage node having a first level, a second storage node which is formed on a second area having second conductive type of the area, the second storage node having a second level opposite to the first level and a well boundary which is sandwiched between the first area and the second area, wherein the second storage node has two diagonal lines, thereby, the first area having a first part sandwiched between the diagonal lines extended from the second storage node through the well boundary, and a second part which is the other part of the first part, wherein the first storage node is placed outside a region between the extended lines of two diagonal lines extending from the second storage node to the well boundary direction, and wherein the second storage node is placed outside a region between the extended lines of two diagonal lines extending from the first storage node to the well boundary direction.

A semiconductor integrated circuit device according to the present invention is a semiconductor integrated circuit device in which first and second CMIS circuits for outputting a first or second logic level signal according to an input signal are formed on a semiconductor substrate, wherein the first CMIS circuit comprises a first conductive type MISFET including a first conductive type first storage node diffusion layer for outputting the first logic level signal to the second CMIS circuit, the second CMIS circuit comprises a second conductive type MISFET including a second conductive type second storage node diffusion layer for outputting the second logic level signal to the first CMIS circuit, the first storage node diffusion layer and the second storage node diffusion layer are formed substantially in a rectangular shape, a first rectangular region from the edge of the first storage node diffusion layer opposite to a first gate electrode of the first conductive type MISFET is outside a region between the extended lines of the two diagonal lines extending from a second rectangular region from the edge of the second storage node diffusion layer opposite to a second gate electrode of the second conductive type MISFET to the center of the second gate electrode, and the second rectangular region of the second storage node diffusion layer is outside a region between the extended lines of the two diagonal lines extending from the first rectangular region of the first storage node diffusion layer.

According to the above semiconductor integrated circuit device, in a region other than the region between the extended lines of the two diagonal lines of one rectangular region from one storage node diffusion layer to the center of the gate electrode, the other rectangular region is placed from the other storage node diffusion layer to the center of the gate electrode, so when the passing length of one rectangular region is the maximum on a straight line passing through the rectangular region including both the storage node diffusion layers, the passing length of the other rectangular region becomes the minimum. Therefore when radiation passes through, simultaneous inversion of the logic level in both storage node diffusion layers can be suppressed, so the generation rate of soft errors can be decreased.

A semiconductor integrated circuit device according to the present invention is a semiconductor integrated circuit device in which first and second CMIS circuits for outputting a first or second logic level signal according to an input signal are formed on a semiconductor substrate, wherein the first CMIS circuit comprises a first conductive type MISFET including a first conductive type first storage node diffusion layer for outputting the first logic level signal to the second CMIS circuit, the second CMIS circuit comprises a second conductive type MISFET including a second conductive type second storage node diffusion layer for outputting the second logic level to the first CMIS circuit, the first storage node diffusion layer and the second storage node diffusion layer are formed substantially in a rectangular shape, a gate electrode of an MISFET having a first conductive type first storage node diffusion layer and a gate electrode of an MISFET having a second conductive type second storage node diffusion layer are substantially in parallel with each other, and are placed substantially in parallel with the well boundary, and the first storage node diffusion layer and the second storage node diffusion layer are placed at more distant positions from the well boundary than the first and second gate electrodes.

According to the above semiconductor integrated circuit device, one storage node diffusion layer and the other storage node diffusion layer are placed at more distant positions from each other on both sides of the gate electrode, so the distance of the storage nodes for storing opposite logic is longer. Therefore when radiation passes, the simultaneous inversion of the logic level in both storage node diffusion layers can be suppressed, so the generation rate of soft errors can be decreased.

A semiconductor integrated circuit device according to the present invention is a semiconductor integrated circuit device in which first and second CMIS circuits for outputting a first or second logic level signal according to an input signal are formed on an SOI substrate, wherein the first CMIS circuit are formed by a first drain region, first channel region and first source region, which are placed side by side, and a first conductive type MISFET for outputting the first logic level signal to the second CMIS circuit, the second CMIS circuit is formed by a second drain region, second channel region and second source region which are placed side by side, and a second conductive type MISFET for outputting the second logic level signal to the first CMIS circuit, and the first conductive type MISFET is formed in a region other than the region that overlaps the second drain region, the second channel region and the second source region in a direction in which the second drain region, second channel region and second source region are placed side by side.

According to the above semiconductor integrated circuit device, the MISFETs for storing opposite logic levels are placed in a region other than the region in the source-drain direction, so the straight line passing between the source and the drain of one MISFET does not pass between the source and the drain of the other MISFET. Therefore when radiation passes through, the simultaneous inversion of the logic level in both MISFETs can be suppressed, so the generation rate of soft errors can be decreased.

A design method of a semiconductor integrated circuit device according to the present invention comprising the steps of: determining a shape of a first conductive type first storage node diffusion layer, placed in a first conductive type MISFET of said first CMIS circuit, for outputting a first logic level signal to the second CMIS circuit; determining a shape of a second conductive type second storage node diffusion layer, placed in a second conductive type MISFET of the second CMIS circuit, for outputting the second logic level signal to the first CMIS circuit; determining a position of the first storage node diffusion layer so as to be placed outside a region between the extended lines of the two diagonal lines extending from the second storage node diffusion layer; and determining a position of the second storage node diffusion layer so as to be placed outside a region between the extended lines extending from the two diagonal lines of the first storage node diffusion layer.

According to the above design method of a semiconductor integrated circuit device, in a region other than the region between the extended lines of the two diagonal lines of one storage node diffusion layer, the other storage node diffusion layer is placed, so when the passing length of one storage node diffusion layer is the maximum on a straight line passing through both the storage node diffusion layers, the passing length of the other storage node diffusion layer becomes the minimum. Therefore when radiation passes through, the simultaneous inversion of the logic level of both storage node diffusion layers can be suppressed, so the generation rate of soft errors can be decreased.

According to the present invention, in the semiconductor integrated circuit device comprising CMIS circuits, the generation of soft errors can be suppressed with a simple configuration.

### BRIEF DESCRIPTION OF THE DRAWINGS

The above and other objects, advantages and features of the present invention will be more apparent from the following description taken in conjunction with the accompanying drawings, in which:

FIG. 1 is a circuit diagram depicting the configuration of the latch circuit used for the semiconductor integrated circuit according to the present invention;

FIG. 2 is a diagram depicting the layout configuration of the semiconductor integrated circuit according to the present invention;

FIG. 3 is a diagram depicting the positional relationship of the elements of the semiconductor integrated circuit according to the present invention;

FIG. 4 is a diagram depicting the positional relationship of the elements of the semiconductor integrated circuit according to the present invention;

FIG. 5 is a graph depicting the characteristics of the elements of the semiconductor integrated circuit according to the present invention;

FIG. 6 is a diagram depicting the layout configuration of the semiconductor integrated circuit according to the present invention;

FIG. 7 is a diagram depicting the layout configuration of the semiconductor integrated circuit according to the present invention;

FIG. 8 is a diagram depicting the positional relationship of the elements of the semiconductor integrated circuit according to the present invention;

FIG. 9 is a diagram depicting the node area of an element of the semiconductor integrated circuit according to the present invention;

FIG. 10 is a circuit diagram depicting the latch circuit used for a conventional semiconductor integrated circuit;

FIG. 11 is a cross-sectional view depicting the configuration of the CMIS circuit used for a conventional semiconductor integrated circuit; and

FIG. 12 is a perspective cross-sectional view depicting the configuration of a MISFET with an SOI structure used for a conventional semiconductor integrated circuit.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

### Embodiment 1

First a semiconductor integrated circuit device according to Embodiment 1 of the present invention will be described. The semiconductor integrated circuit device has two CMIS circuits holding the logic information opposite from each other, and is characterized in that the storage node diffusion layer of the NMISFET for holding a first logic information in one CMIS circuit and the storage node diffusion layer of the PMISFET-for holding a second logic information in the other CMIS circuit are placed at locations distant from each other excluding the extended lines of the respective diagonal lines.

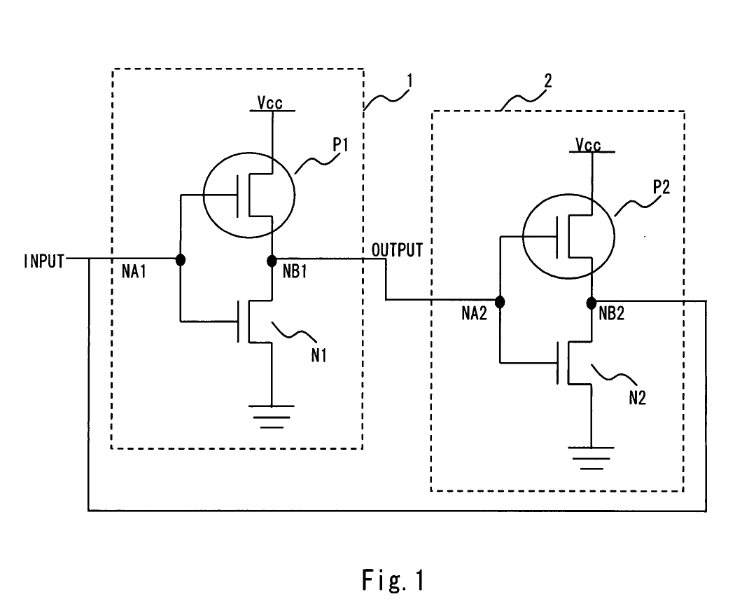

Now the configuration of the latch circuit used for the semiconductor integrated circuit device according to the present embodiment will be described with reference to FIG. 1. As FIG. 1 shows, this latch circuit is comprised of the CMIS inverter (first CMIS circuit) 1 and the CMIS inverter (second CMIS circuit) 2. The CMIS inverters 1 and 2 output a signal (data) at logic level according to the input signal respectively. The output of the CMIS inverter 1 is input to the CMIS inverter 2, and the output of the CMIS inverter 2 is input to the CMIS inverter 1, and data with opposite logic from each other is output so as to hold the data stably.

The CMIS inverter 1 has the PMISFET P1 and the NMISFET N1, and the CMIS inverter 2 has the PMISFET P2 and the NMISFET N2.

PMISFET P1 and NMISFET N1 are connected between the power supply Vcc and the ground potential GND in series. In other words, the source of PMISFET is connected to the power supply Vcc, and the source of NMISFET N1 is connected to the ground potential GND. The gates of PMISFET P1 and NMISFET N1 are inter-connected, and each gate becomes an input node NA1, and signals from the outside are input to the input node NA1. The drains of PMISFET P1 and NMISFET N1 are inter-connected, and each drain becomes the storage node NB1. The storage node NB1 is a node for storing and outputting the logic data, and signals are output to the outside via the storage node NB1, and also the signals are output to the CMIS inverter 2.

Just like the case of the CMIS inverter 1, PMISFET P2 and NMISFET N2 are connected between the power supply Vcc and the ground potential GND in series, the signals from the storage node NB1 of the CMIS inverter 1 are input to the input node NA2, and the signals are output from the storage node NB2 to the input node NA1 of the CMIS inverter 1.

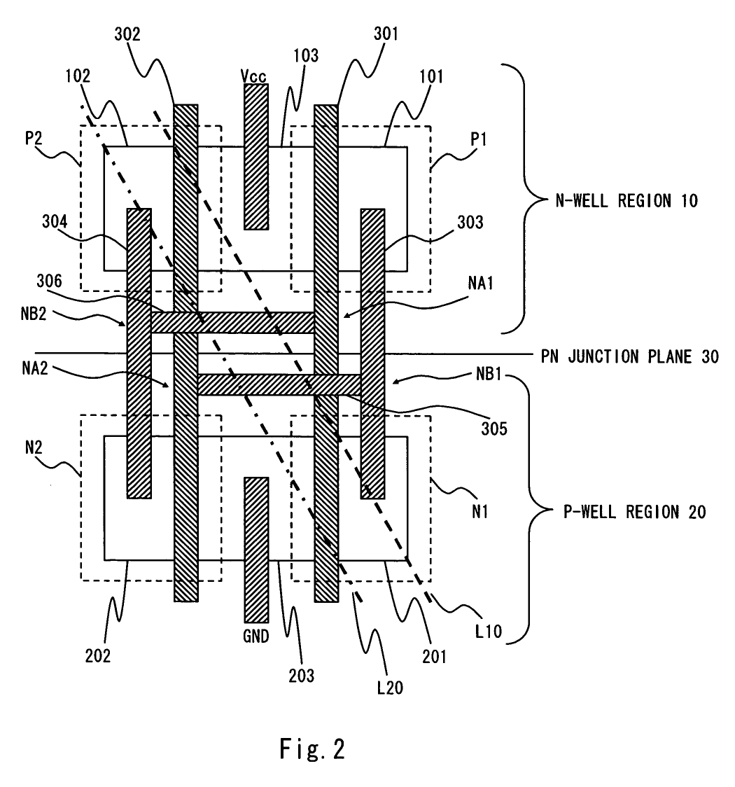

Now the layout of the latch circuit in FIG. 1 will be described with reference to FIG. 2. The latch circuit according to the present embodiment is formed with one layer of the inter-connect layer.

On the semiconductor substrate, the N-well region 10 and the P-well region 20 are formed, and the plane where the N-well region 10 and the P-well region 20 adjacent to each other is the Well boundary 30. On the front face of the semiconductor substrate, the gate electrodes 301 and 302 are formed stretching in a direction vertical to the Well boundary 30 via the insulation film (not illustrated).

In the N-well region 10, the power supply diffusion layer 103 is formed between the gate electrode 301 and the gate electrode 302, the storage node diffusion layer 101 is formed in a region at the opposite side of the power supply diffusion layer 103 of the gate electrode 301, and the storage node diffusion layer 102 is formed in a region at the opposite side of the power supply diffusion layer 103 of the gate electrode 302. The storage node diffusion layer 101, gate electrode 301 and power supply diffusion layer 103 constitute the PMISFET P1, and the storage node diffusion layer 102, gate electrode 302 and power supply diffusion layer 103 constitute the PMISFET P2.

The power supply diffusion layer 103 is a P-type diffusion layer, and is connected to the power supply Vcc as a common source of PMISFET P1 and P2. The storage node diffusion layer 101 is a P-type diffusion layer, and outputs the data being held to the storage node NB1 of the drain of PMISFET P1. In the same way, the storage node diffusion layer 102 is a P-type diffusion layer, and outputs the data being held to the storage node NB2 as the drain of PMISFET P2.

In the P-well region 20, the power supply diffusion layer 203 is formed in the region between the gate electrode 301 and gate electrode 302, and the storage node diffusion layer 201 is formed in a region on the opposite side of the power supply diffusion layer 203 of the gate electrode 301, and the storage node diffusion layer 202 is formed in a region on the opposite side of the power supply diffusion layer 203 of the gate electrode 302. The storage node diffusion layer 201, gate electrode 301 and power supply diffusion layer 203 constitute the NMISFET N1, and the storage node diffusion layer 202, gate electrode 302 and power supply diffusion layer 203 constitute the NMISFET N2.

The power supply diffusion layer 203 is an N-type diffusion layer, and is connected to the ground potential GND as a common source of NMISFET N1 and N2. The storage node diffusion layer 201 is an N-type diffusion layer, and outputs the data being held to the storage node NB1 as a drain of NMISFET N1. In the same way, the storage node diffusion layer 202 is an N-type diffusion layer, and outputs the data being held to the storage node NB2 as the drain of NMISFET N2.

The inter-connect 303 is formed stretching from the storage node diffusion layer 101 to the storage node diffusion layer 201 so as to be vertical to the well boundary 30. The inter-connect 305 is formed stretching from the center area of the inter-connect 303 to the center area of the gate electrode 302 so as to be parallel to the Well boundary 30. The inter-connect 303 and the storage node diffusion layers 101 and 201 and the inter-connect 305 and gate electrode 302 are connected via contacts respectively (contacts are not illustrated), and the storage node diffusion layer 101, storage node diffusion layer 201 and gate electrode 302 are electrically connected. The inter-connect 303 becomes the storage node NB1, and the gate electrode 302 becomes the input node NA2.

In the same way, the inter-connect 304 is formed stretching from the storage node diffusion layer 102 to the storage node diffusion layer 202, and the inter-connect 306 is formed stretching from the center area of the inter-connect 304 to the center area of the gate electrode 301, and the storage node diffusion layer 102, storage node diffusion layer 202 and gate electrode 301 are electrically connected. The inter-connect 304 becomes the storage node NB2, and the gate electrode 301 becomes the input node NA1.

Each diffusion layer is formed to be symmetrical with respect to the well boundary 30. In other words, the storage node diffusion layer 101 and storage node diffusion layer 201, the storage node diffusion layer 102 and storage node diffusion layer 202, and the power supply diffusion layer 103 and power supply diffusion layer 203 have similar shapes respectively, and are formed in positions facing each other with respect to the Well boundary 30 respectively. The storage node diffusion layers 101 and 102 and the storage node diffusion layers 201 and 202 are rectangular diffusion layers, where the short side is in parallel with the Well boundary 30, and the long side is vertical to the Well boundary.

The characteristics of the present embodiment is the positional relationships of the storage node diffusion layer 101 and storage node diffusion layer 202, and of the storage node diffusion layer 102 and storage node diffusion layer 201 respectively, that is, positions of the two storage node diffusion layers holding logic information opposite from each other in the respectively CMIS circuit. For example, on the extended line (L10) of the diagonal line of the storage node diffusion layer 201 of NMISFET N1 for storing the “H level (data 1)”, the storage node diffusion layer 102 of PMISFET P2 for storing the “L level (data 0) is not placed, and the storage node diffusion layer 102 is formed at a position distant from the storage node diffusion layer 201 excluding the extended line of this diagonal line. In the same way, on the extended line (L20) of the diagonal line of the storage node diffusion layer 102 of PMISFET P2 for storing the “L level”, the storage node diffusion layer 201 of NMISFET N1 for storing the “H level” is not placed, and the storage node diffusion layer 201 is formed at a position distant from the storage node diffusion layer 102 excluding this extended line of the diagonal line.

Now the positional relationship of the storage node diffusion layers will be described. As FIG. 2 shows, the source-drain diffusion layer of the MISFET is generally a rectangle. The charge collection quantity when radiation passes through the diffusion layer is in proportion to the overlap length of the diffusion layer (depletion layer) and the locus of the secondary ions. The present embodiment minimizes conditions when soft errors most likely occur, that is when radiation simultaneously passes through the storage node diffusion layer (first storage node diffusion layer) of NMISFET (first conductive type MISFET) for storing the “H level (first logic level)” and the storage node diffusion layer (second storage node diffusion layer) of PMISFET (second conductive type MISFET) for storing the “L level (second logic level)”, this passing length is minimized.

In terms of a regular rectangle, if the length of the two sides of the two rectangles are (a*b) and (c*d), and these rectangles are placed arbitrarily on a same plane (without overlapping), then the length (passing length D) when one straight line passing through both of the rectangles crosses (overlaps) both rectangles is given by the following Expression 1 when the straight line passes through opposite sides (two sides facing each other) of at least one rectangle. In Expression 1, min(x, y) indicates the smaller one of x and y.
min[(a, b), min(c, d)]≦D≦(a²+b²)^{1/2}+(c²+d²)^{1/2} (Expression 1)

If this passing length D is regarded as a locus when radiation (ions) passes through the diffusion layer (depletion layer), then it means that the soft error rate (SER) becomes higher (aggravated) as the passing length D becomes longer.

Here the passing length D is divided into the length Dn of the portion of the storage node diffusion layer of NMISFET for storing the “H level” where radiation passes through, and the length Dp of the portion of the storage node diffusion layer of PMISFET for storing the “L level” where radiation passes through, then the passing length D is given by Expression 2.
D=Dn+Dp (Expression 2)

Dn indicates the index when electrons are collected in the storage node diffusion layer of the NMISFET for storing the “H level” information, and Dp indicates the index when holes are collected in the storage node diffusion layer of the PMISFET for storing the “L level” information. Actually the collection rate of electrons and that of holes are different between the N-type diffusion layer and the P-type diffusion layer, in consideration of above difference, the passing length D′ is given by Expression 3.
D′=Dn+αDp(0<α<1) (Expression 3)

In Expression 3, α is a factor for correcting the difference of the collection rates of electrons and holes in the N-type diffusion layer and the P-type diffusion layer. For example, as miniaturization and voltage decrease of semiconductor devices advance, the ratio of the contribution of Dp to SER increases, so α increases.

It is preferable to place the storage node diffusion layers such that the passing length D′ is minimized. Particularly in the present embodiment, it is preferable that when one of Dp and Dn is at the maximum or at a value near the maximum, the storage node diffusion layer of the MISFET is placed such that the other of Dp and Dn is minimized. For example, the positional relationship to satisfy the following Expression 4 is used. In Expression 4, max(x, y) indicates the greater one of x and y.
min(a, b)+min(c, d)≦D′≦max(a, b)+max(c, d) (Expression 4)

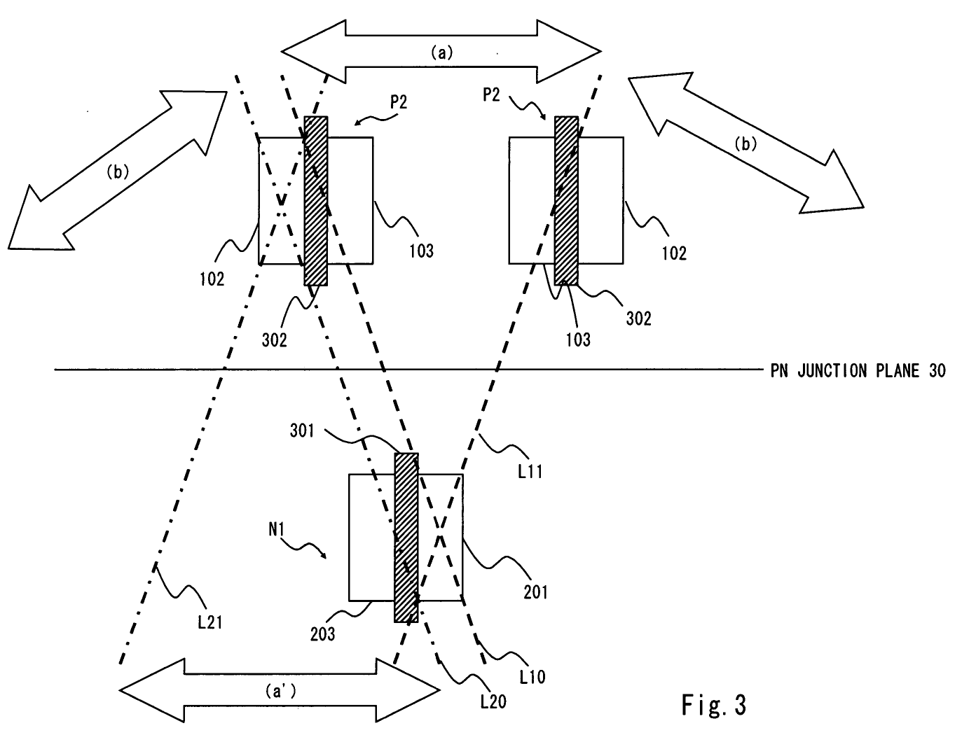

In other words, the total of the passing lengths of the two storage node diffusion layers is set to be smaller than the sum of the long sides of the two storage node diffusion layers (right side of Expression 4). FIG. 3 shows an example when the two storage node diffusion layers are placed in positions which satisfy Expression 4. In FIG. 3, when the diagonal line of the storage node diffusion layer 201 (102) is extended to the storage node 102 (201), the extended lines do not cross the two sides of the other diffusion layer. Here the positions of the storage node diffusion layer 201 and the storage node diffusion layer 102 are described, but the storage node 202 and the storage node 101 are also placed in similar positions.

For example, in the case of the storage node diffusion layer 201 of the NMISFET N1, the storage node diffusion layer 102 of the PMISFET P2 holding an opposite logic-level is formed in the region between the two straight lines when the two diagonal lines of the storage node diffusion layers 201 are extended toward the Well boundary 30, that is the region between the extended lines (L10, L11) of the two diagonal lines of the storage node diffusion layer 201, excluding the region on the side of the short side of the storage node diffusion layer 201 ((a) in FIG. 3). In other words, the storage node diffusion layer 102 is formed in the region on the side of the long side of the storage node diffusion layer 201 ((b) in FIG. 3) out of the region between the extended lines of the two diagonal lines of the storage node diffusion layer 201. In the same way, the storage node diffusion layer 201 of the NMISFET N1 is formed in the region excluding the region between the extended lines (L20, L21) of the two diagonal lines of the storage node diffusion layer 102 ((a′) in FIG. 3).

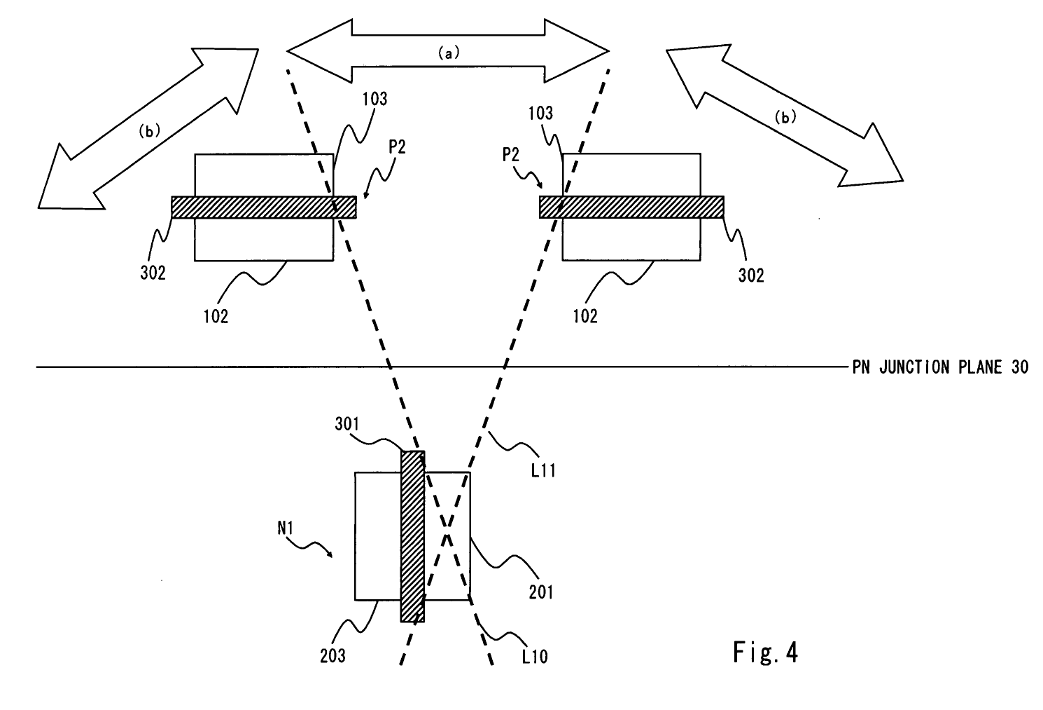

When the gate electrode 301 of the NMISFET N1 and the gate electrode 302 of the PMISFET P2 are placed vertical to each other, as FIG. 4 shows, that is when the gate electrode 301 is vertical to the Well boundary 30 and the gate electrode 302 is parallel with the Well boundary 30 as well, the storage node diffusion layers are placed in the same way as FIG. 3. In other words, the storage node diffusion layer 102, for holding opposite logic, is not formed in the region at the side of the short side ((a) in FIG. 4) out of the region between the two diagonal lines (L10, L11) of the storage node diffusion layer 201, and the storage node diffusion layer 102 is formed in the region at the side of the long side ((b) in FIG. 4) out of the region between the two diagonal lines of the storage node diffusion layer 201. Here, concerning the placement of the PMISFET, the storage node diffusion layer 102 is placed at a side closer to the Well boundary 30, and the power supply diffusion layer 103 is placed at a side more distant there from, but the power supply diffusion layer 103 may be placed at a side closer to the Well boundary 30, and the storage node diffusion layer 102 may be placed at a side more distant there from, so that the storage node diffusion layer 102 becomes more distant from the storage node diffusion layer 201.

In this way, according to the present embodiment, the storage node diffusion layer for holding the information of opposite logic is formed at a position distant from the diagonal lines of the storage node diffusion layer, so when radiation passes through and the passing length in one storage node diffusion layer is the maximum, the passing length of the other storage node diffusion layer becomes the minimum. Therefore the status when soft errors most likely occur, just like the case of simultaneously inverting the two storage node diffusion layers holding information of logic opposite from each other, can be prevented, therefore the generation of soft errors can be suppressed.

Also by miniaturization, the storage node diffusion layer is becoming smaller, and the power supply voltage (storage node potential) is decreased to insure reliability and to decrease power consumption. By this, the stored charge quantity of the storage node decreases. On the other hand, the collection of charges generated by radiation decreases since the storage node diffusion layer area decreases. So the soft error rate (SER) of the next generation products is generally determined by the trade-off of a “decrease in the stored charge quantity” and a “decrease in the charge collection”.

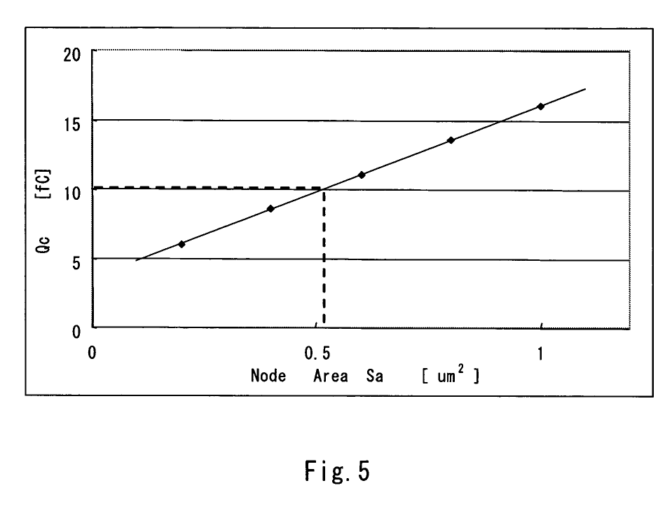

Now the conditions when the effect of the present embodiment becomes conspicuous will be described. A factor to determine the SER is the minimum charge quantity (critical charge: Qc) required to invert the stored node logic of this circuit. FIG. 5 shows the charge of the Qc caused by miniaturization. FIG. 5 shows the relationship between the storage node diffusion layer area (PMISFET+NMISFET in this case) Sa and the critical charge Qc, where the critical charge Qc is the critical charge quantity of the flip-flop circuit in a CMIS configuration calculated by simulation. The holding voltage in each storage node diffusion layer area Sa is changed according to a general scaling rule.

Generally the charges to be generated in an Si substrate by radiation are 10 fC-15 fC/μm in the case of α particles, and 100 fC-150 fC/μm in the case of high energy neutrons. Simply stated, if the gate width W of a MOSFET is 1 μm, then about 10 fC of charges generated by a particles may be collected. Therefore in the case of a circuit of which the critical charge quantity is 10 fC or less, it is possible that SER becomes extremely poor.

In FIG. 5, the storage node diffusion layer area Sa for the critical charge quantity Qc to become 10 fC is about 0.5 μm². The voltage of the storage node diffusion layer at this time is 1.8V. Therefore the SER may become poor when the area of the storage node diffusion layer Sa is about 0.5 μm² or less or when the voltage of the storage node diffusion layer is 1.8V or less, where the effect when the present embodiment is applied is high. These values change depending on the power supply voltage to be applied to this storage node diffusion layer and simulation conditions (conditions to judge the critical charge quantity, charge quantity to be generated and method of determining parasitic parameters), but the critical charge quantity itself changes little. The present embodiment becomes more effective as the area of the storage node diffusion layer decreases and the power supply voltage decreases even more in future.

### Embodiment 2

The semiconductor circuit device according to Embodiment 2 of the present invention will now be described. The semiconductor integrated circuit device according to the present embodiment is characterized in that when the storage node diffusion layers of each MISFET is stretched in parallel with the Well boundary, the storage node diffusion layers for holding the logic opposite from each other are placed in positions facing each other with respect to the Well boundary there between. In the semiconductor integrated circuit device according to the present embodiment, description of the configuration of the latch circuit, which is the same as FIG. 1, will be omitted.

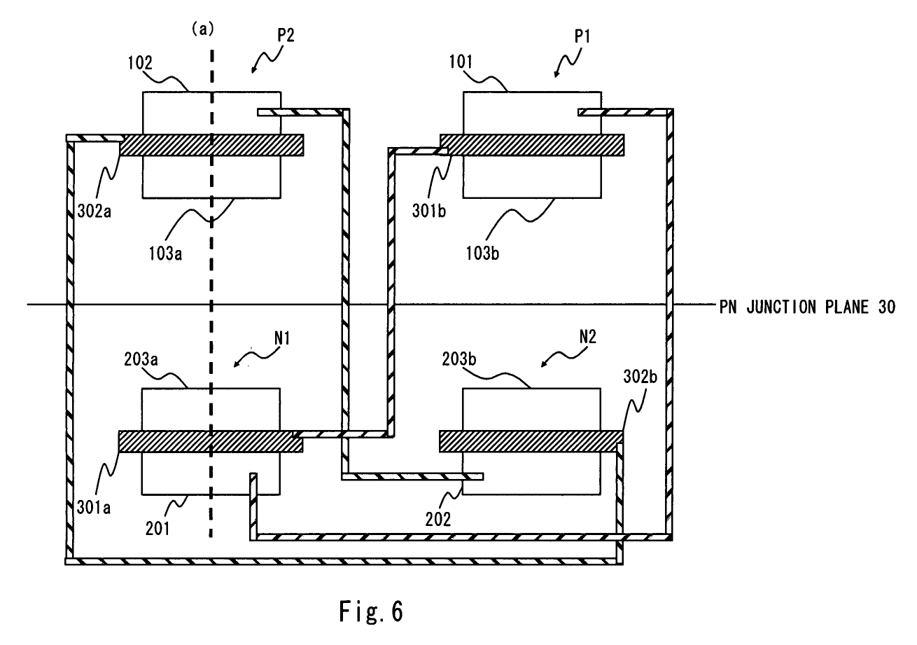

The layout of the latch circuit according to the present embodiment will be described with reference to FIG. 6. FIG. 6 shows the placement of each MISFET and the connection relationship. In FIG. 6, composing elements the same as those in FIG. 2 are denoted with the same reference symbols.

In this example, the gate electrodes of the PMISFET P1 and P2 and the NMISFET N1 and n2 are formed stretching in parallel with the Well boundary 30. The storage node diffusion layer and the power supply diffusion layer of each MISFET are rectangular, and are formed stretching in parallel with the Well boundary 30, just like the gate electrodes.

In the duplicating areas in the stretching direction of the gate electrode 302a, the storage node diffusion layer 102 and the power supply diffusion layer 103a of the PMISFET P2, gate electrode 301b, storage node diffusion layer 101 and power supply diffusion layer 103b of the PMISFET P1 are formed respectively. In the same way, in the duplicated areas in the stretching direction of the gate electrode 301a, storage node diffusion layer 201 and power supply diffusion layer 203a of the NMISFET N1, the gate electrode 302b, storage node diffusion layer 202 and power supply diffusion layer 203b of the NMISFET N2 are formed.

The gate electrode 301 is divided into the gate electrode 301a of the NMISFET N1 and the gate electrode 301b of the PMISFET P1, and are connected by inter-connects. The gate electrode 302 is divided into the gate electrode 302a of the PMISFET P2 and the gate electrode 302b of the NMISFET N2, and are connected by inter-connects.

The power supply diffusion layer 203 is divided into the power supply diffusion layer 203a of the NMISFET N1 and the power supply diffusion layer 203b of the NMISFET N2, and power is supplied thereto respectively. The power supply diffusion layer 103 is divided into the power supply diffusion layer 103a of the PMISFET P1 and the power supply diffusion layer 103b of the PMISFET P2, and power is supplied thereto respectively.

The storage node diffusion layer 101 of the PMISFET P1 and the storage node diffusion layer 201 of the NMISFET N1 are connected, and the PMISFET P1 and NMISFET N1 constitute the CMIS inverter 1. The storage node diffusion layer 102 of the PMISFET P2 and the storage node diffusion layer 202 of the NMISFET N2 are connected, and the PMISFET P2 and the NMISFET N2 constitute the CMIS inverter 2.

In each MISFET, the storage node diffusion layer is formed at a more distant position than the power supply diffusion layer and the gate electrode from the Well boundary 30. For example, in the PMISFET P2 and the NMISFET N1, the power supply diffusion layers 103a and 203a and the gate electrodes 301a and 302a are formed at positions closer to the Well boundary 30, and the storage node diffusion layers 102 and 201 are formed at positions more distant from the Well boundary 30.

Also in the present embodiment, the storage node diffusion layers of the MISFET holding logic opposite from each other are formed at positions facing each other with respect to the Well boundary. For example, in the PMISFET P2 and the NMISFET N1, the storage node diffusion layers 102 and 201 are formed at positions facing each other with respect to the Well boundary 30. In other words, the line passing through the storage node diffusion layer 201 on a straight line in parallel with the short side and the line passing through the storage node diffusion layer 201 on a straight line in parallel with the short side are set to match. Particularly the center line stretching in the short side direction of the storage node diffusion layer 201 and the center line stretching in the short side direction of the storage node diffusion layer 102 are set to roughly match ((a) in FIG. 6).

In the present embodiment, when the storage node diffusion layers stretch in parallel with the Well boundary, the passing length of radiation in both storage node diffusion layers becomes the length of the short side respectively if the storage node diffusion layers are placed in positions facing each other with respect to the Well boundary, so radiation does not pass through the storage node diffusion layers at maximum length. Therefore the status when soft errors will most likely occur by the simultaneous inversion of the two storage node diffusion layers holding information of logic opposite from each other can be avoided, so the generation of soft errors can be suppressed.

Also by keeping the storage node diffusion layers holding information of logic opposite from each other are more distant from the power supply diffusion layer and gate electrode via the Well boundary, and the collection of electrons and holes when radiation passes can be decreased, so soft errors can be further decreased.

### Embodiment 3

The semiconductor integrated circuit device according to Embodiment 3 will now be described. The present embodiment has a layout configuration similar to Embodiment 2, however only the connection relationship is changed.

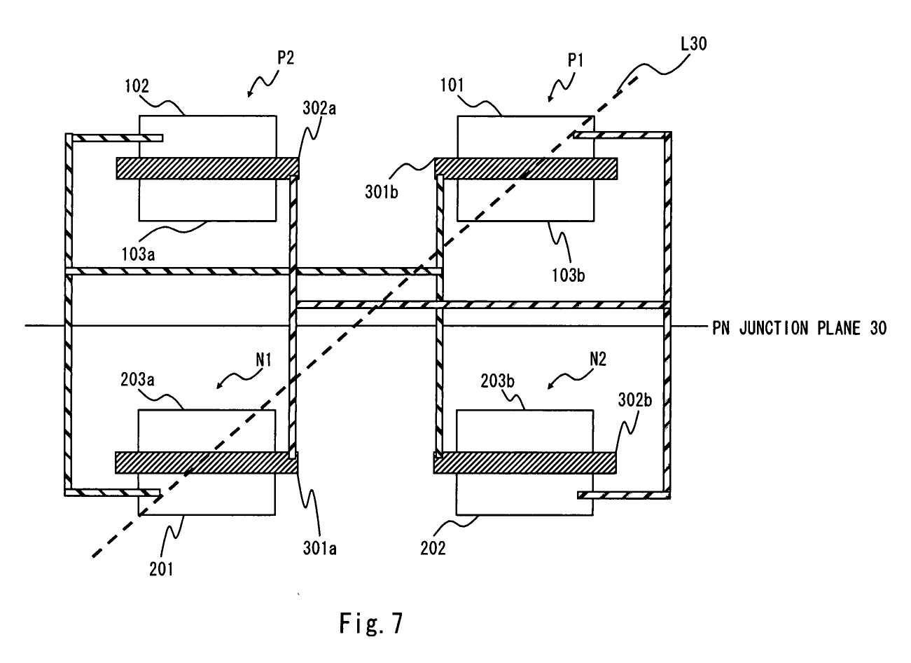

FIG. 7 shows the layout and the connection relationship of the latch circuit according to the present embodiment, just like FIG. 6. In FIG. 7, the positions of the diffusion layers and the gate electrodes are the same as those in FIG. 6, but the positional relationship of the two storage node diffusion layers is different. In FIG. 7, the gate electrodes and the diffusion layers the same as those in FIG. 6 are denoted with the same reference symbols. In FIG. 7, the positional relationship of the storage node diffusion layer 201 (202) of the NMISFET N1 (N2) and the storage node diffusion layer 101 (102) of the PMISFET P1 (P2) are the same as those in FIG. 6, but the combination of the logic levels is different from FIG. 6.

As described above, when the sum of the straight line (L30) passing through the two diffusion layers of which logical levels are different from each other and the crossing section of both diffusion layers is D, it is preferable that the value of D is smaller in terms of the soft error countermeasure, but in the case of FIG. 7, the storage node diffusion layers 201 and 101 (202 and 102) may be in the positional relationship in the following Expression 5.

short side of storage node diffusion layer 201 (202)+short side of storage node diffusion layer 101 (102)≦D≦(short side of storage node diffusion layer 201 (202))^{1/2}+(short side of storage node diffusion layer 101 (102))^{1/2} (Expression 5)

This is because the two storage nodes are more distant compared with FIG. 6, and D is smaller compared with the case of FIG. 3. The left term in Expression 5 corresponds to the sum of the crossing section (D) when the straight line (L30) of the storage node diffusion layers of which logic levels in FIG. 6 are different from each other passes through the center line of both diffusion layers.

In the case of the present embodiment, when the storage node diffusion layers are stretched in parallel with the Well boundary, the storage node diffusion layers are placed so as to satisfy Expression 5, then just like Embodiment 2, the passing length of both storage node diffusion layers, when radiation passes, becomes the range of the total of the lengths of each short side—total of 2^{1/2} times the length of each side, so radiation does not pass through the storage node diffusion layers at the maximum length. Therefore just like the case of Embodiments 1 and 2, the status where soft errors most like occur can be avoided, so the generation of soft errors can be suppressed.

### Embodiment 4

The semiconductor integrated circuit device according to Embodiment 4 will now be described. The semiconductor integrated circuit device according to the present embodiment is characterized in that a CMIS circuit is comprised of an MISFET in an SOI structure, two MISFETs holding information of logic opposite from each other are placed in the region other than the extension of the channel region, and in the region other than the region in a direction where the diffusion layers line up.

In the semiconductor circuit device according to the present embodiment, the configuration of the latch circuit and the basic layout are the same as FIG. 1 and FIG. 2, so description thereof will be omitted. In the case of the SOI structure, the Well boundary 30 in FIG. 2 is not formed.

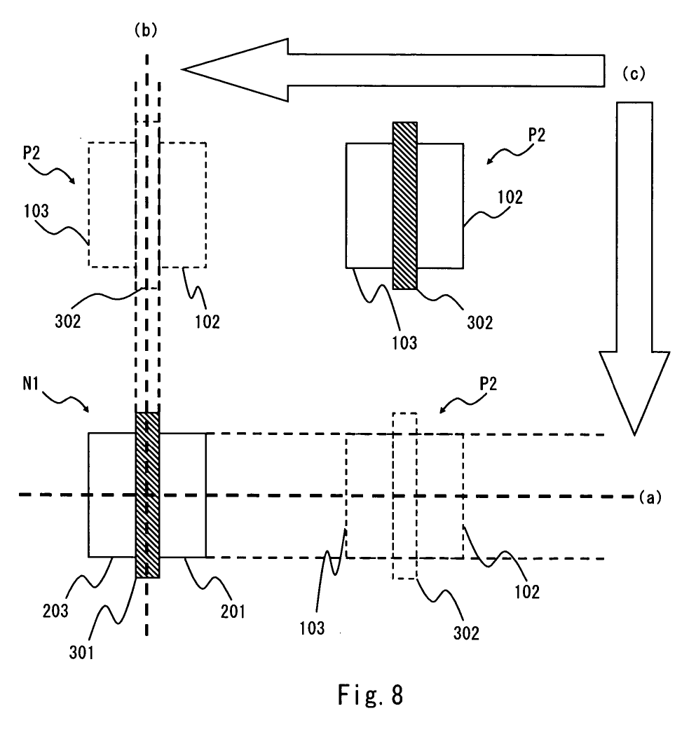

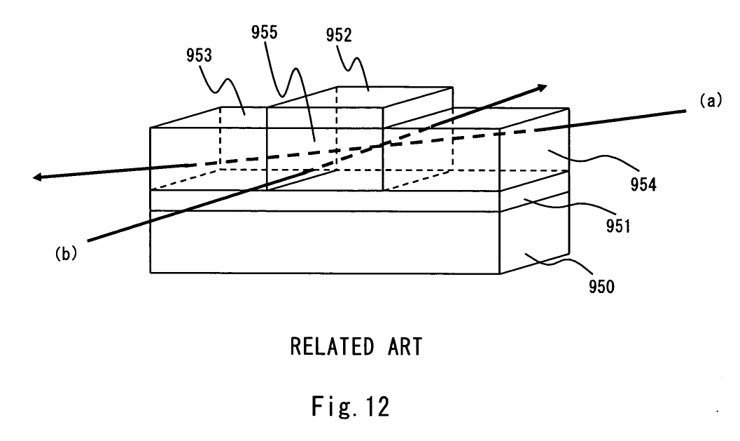

FIG. 8 shows the positional relationship of MISFETs according to the present embodiment. Here each MISFET is the MISFET having the SOI structure shown in FIG. 12. In other words, on the semiconductor substrate and insulation film being stacked, the source-drain-channel layer comprised of the source region, channel region (body region) and drain region are formed, and a gate electrode is formed on the channel region via the insulation film. An MISFET with an SOI structure, a structure where the well region does not exist or where a thin well region (not illustrated) exists under the source-drain-channel shown in FIG. 12 may be used.

As FIG. 8 shows, in the case of the NMISFET N1, for example, in duplicated regions ((a) in FIG. 8) in the direction of the power supply diffusion layer (source diffusion layer) 203 of the NMISFET N1, the channel region under the gate electrode 301 and the storage node diffusion layer (drain diffusion layer) 201 line up, the power supply diffusion layer 103 of the PMISFET P2, which holds opposite logic, the channel region under the gate electrode 302 and the storage node diffusion layer 102 are not placed. In a duplicated area ((b) in FIG. 8) of the channel region in a direction where the channel region under the gate electrode 301 stretches, the channel region under the gate electrode 302 is not placed. And the PMISFET P2 is placed in the region (c) between this region (a) and region (b).

In this embodiment, when the CMIS circuit is comprised of MISFETs with an SOI structure, the two MISFETs holding logic opposite from each other are not placed side by side in a direction where the channel region is stretched or diffusion layers line up, so radiation passing through both channel regions simultaneously and radiation passing through both source-drain-channel layers simultaneously are prevented. Therefore the status when soft errors most likely occur by simultaneous inversion of two MISFETs holding information of logic opposite from each other can be avoided, so the generation of soft errors can be suppressed.

An MISFET with an SOI structure is not limited to the configuration in FIG. 12, but may have a configuration comprising a fin type source-drain-channel layer, where the gate electrode is placed above the source-drain-channel layer, and also covers the side faces of the source-drain-channel layer.

### Other embodiments

In the above examples the layout configurations of semiconductor integrated circuit devices were described, but the present invention can also be applied to a design method for designing this layout. If the present invention is applied to the semiconductor integrated circuit device shown in FIG. 3, the shape of the storage node diffusion layer 201 of the NMISFET N1 is decided, the shape of the storage node diffusion layer 102 of the PMISFET P2 for holding the opposite logic is decided, the position of the storage node diffusion layer 102 is decided so as to be in the range in FIG. 3, such as the region other than the region between the extended lines of the two diagonal lines of the storage node diffusion layer 201, and the position of the storage node diffusion layer 201 is decided so as to be placed in the region other than the region between the extended lines of the two diagonal lines of the storage node diffusion layer 102.

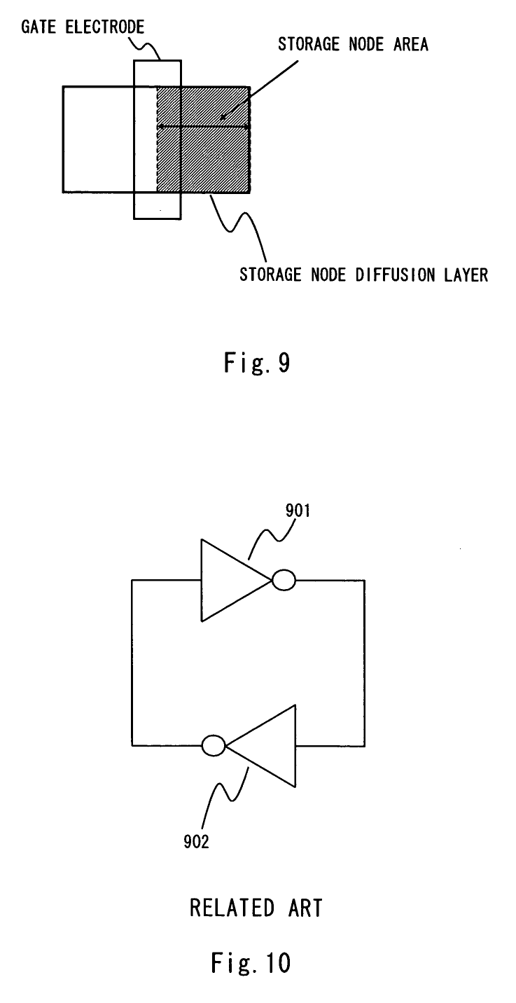

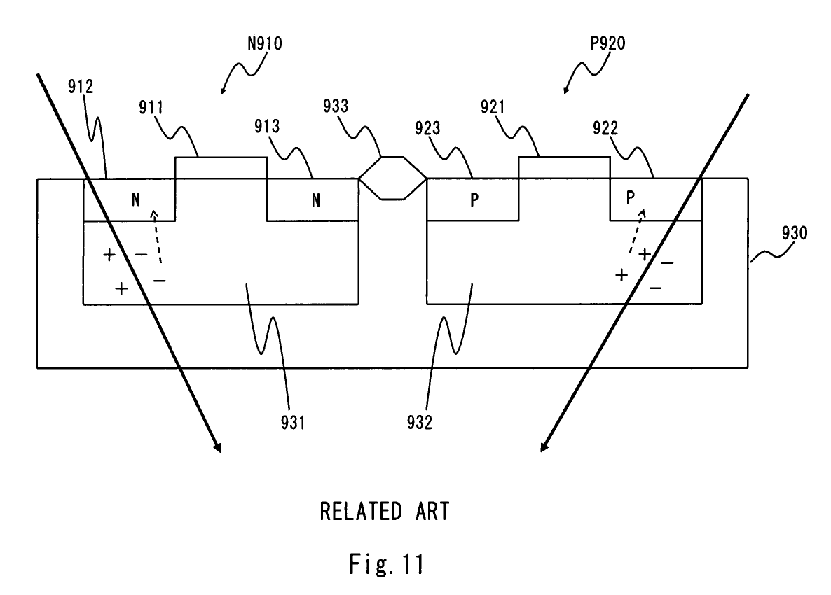

In the above examples, the storage node diffusion layers are placed based on the shapes of the storage node diffusion layers, but may be based on the depletion layer since the depletion layer actually collects electrons and holes generated by radiation. However it is difficult to consider the depletion layer width in the layout design stage. Instead of the depletion layer, as shown in FIG. 9, it is regarded that the size of the storage node diffusion layer reaches the center of the source-drain (center of gate electrode), and this region may be set as the storage node area. In other words, the relationships of Expression 1 to 5 are satisfied for the rectangular region of the storage node area for the edge of the storage node diffusion layer facing the gate electrode to the center of the gate electrode. For example, the first rectangular region of the storage node diffusion layer 102 may be placed outside the region between the two diagonal lines of the second rectangular region of the storage node diffusion layer 201.

In the above example, the latch circuit in FIG. 1 was described, but the present invention is not limited to this, but can be applied to a data holding circuit with other configurations if the circuit holds data by mutually outputting data with opposite logic between a plurality of CMIS circuits. The gate insulation film of an MISFET is not limited to an oxide film, but may be a high dielectric constant film or a film containing these films (composite film).

It is apparent that the present invention is not limited to the above embodiment and it may be modified and changed without departing from the scope and spirit of the invention.

What is claimed is:

1. A semiconductor integrated circuit device which is formed on an area comprising:
a first storage node which is formed on a first area having a first conductive type of the area, the first storage node having a first level;
a second storage node which is formed on a second area having second conductive type of the area, the second storage node having a second level opposite to the first level; and
a well boundary which is sandwiched between the first area and the second area, wherein
the second storage node has two diagonal lines, thereby, the first area having a first part sandwiched between the diagonal lines extended from the second storage node through the well boundary, and a second part which is the other part of the first part,
wherein the first storage node is placed outside a region between the extended lines of two diagonal lines extending from the second storage node to the well boundary direction, and wherein the second storage node is placed outside a region between the extended lines of two diagonal lines extending from the first storage node to the well boundary direction.

2. A semiconductor integrated circuit device in which first and second CMIS circuits for outputting a first or second logic level signal according to an input signal are formed on a semiconductor substrate, wherein
the first CMIS circuit comprises a first conductive type MISFET including a first conductive type first storage node diffusion layer for outputting the first logical level signal to the second CMIS circuit,
the second CMIS circuit comprises a second conductive type MISFET including a second conductive type second storage node diffusion layer for outputting the second logic level signal to the first CMIS circuit,
the first storage node diffusion layer and the second storage node diffusion layer are formed substantially in a rectangular shape,
a first rectangular region from the edge of the first storage node diffusion layer opposite to a first gate electrode of the first conductive type MISFET to the center of the first gate electrode is outside a region between the extended lines of two diagonal lines extending from a second rectangular region from the edge of the second storage node diffusion layer opposite to a second gate electrode of the second conductive type MISFET to the center of the second gate electrode, and
the second rectangular region of the second storage node diffusion layer is outside a region between the extended lines of two diagonal lines extending from the first rectangular region of the first storage node diffusion layer.

3. The semiconductor integrated circuit device according to claim 2, wherein the diffusion layer area of at least one of the first storage node diffusion layer and the second storage node diffusion layer is substantially 0.5 μm² or less.

4. The semiconductor integrated circuit device according to claim 2, wherein the voltage in standard use status of the first CMIS circuit and the second CMIS circuit is 1.8V or less.

5. The semiconductor integrated circuit device according to claim 2, wherein each of the first conductive type MISFET and second conductive type MISFET constituting the first and second CMIS circuits has one Well boundary.

6. The semiconductor integrated circuit device according to claim 2, wherein
the first conductive type MISFET comprises a first gate electrode formed in parallel with the first storage node diffusion layer,
the second conductive type MISFET further comprises a second gate electrode formed in parallel with the second storage node diffusion layer, and
the first gate electrode and the second gate electrode are formed substantially in parallel.

7. The semiconductor integrated circuit device according to claim 2, wherein
the first gate electrode of the first conductive type MISFET is formed in parallel with the first storage node diffusion layer,
the second gate electrode of the second conductive type MISFET is formed in parallel with the second storage node diffusion layer, and
the first gate electrode and the second gate electrode are formed substantially in parallel.

8. The semiconductor integrated circuit device according to claim 6, wherein
the first conductive type MISFET is formed in a second conductive type well region,
the second conductive type MISFET is formed in a first conductive type well region, and
the first gate electrode and the second gate electrode are formed substantially vertical to the junction plane of the first conductive type well region and the second conductive type well region.

9. The semiconductor integrated circuit device according to claim 2, wherein
the first conductive type MISFET comprises a first gate electrode formed in parallel with the first storage node diffusion layer,
the second conductive type MISFET comprises a second gate electrode formed in parallel with the second storage node diffusion layer, and
the first gate electrode and the second gate electrode are formed substantially vertical to each other.

10. The semiconductor integrated circuit device according to claim 2, wherein
the first gate electrode of the first conductive type MISFET is formed in parallel with the first storage node diffusion layer,
the second gate electrode of the second conductive type MISFET is formed in parallel with the second storage node diffusion layer, and
the first gate electrode and the second gate electrode are formed roughly vertical to each other.

11. The semiconductor integrated circuit according to claim 9, wherein
the first conductive type MISFET is formed in a second conductive type well region,
the second conductive type MISFET is formed in a first conductive type well region,
the first gate electrode is formed substantially in parallel with the junction plane of the first conductive type well region and the second conductive type well region, and
the second gate electrode is formed substantially vertical to the junction plane.

12. A semiconductor integrated circuit device in which first and second CMIS circuits for outputting a first or second logic level signal according to an input signal are formed on a semiconductor substrate, wherein
the first CMIS circuit comprises a first conductive type MISFET including a first conductive type first storage node diffusion layer for outputting the first logic level signal to the second CMIS circuit,
the second CMIS circuit comprises a second conductive type MISFET including a second conductive type second storage node diffusion layer for outputting the second logic level signal to the first CMIS circuit,
the first storage node diffusion layer and the second storage node diffusion layer are formed substantially
in a rectangular shape, a gate electrode of an MISFET having the first conductive type first storage node diffusion layer and a gate electrode of an MISFET having the second conductive type second storage node diffusion layer are substantially in parallel with each other and are placed substantially in parallel with the Well boundary, and
the first storage node diffusion layer and the second storage node diffusion layer are placed at more distant positions from the Well boundary than the first and second gate electrodes.

13. The semiconductor integrated circuit device according to claim 12, wherein the first storage node diffusion layer and the second storage node diffusion layer are placed facing each other with the Well boundary interposed therebetween.

14. The semiconductor integrated circuit device according to claim 12, wherein the first storage node diffusion layer and the second storage node diffusion layer are formed so that the center line extending in the width direction of the first storage node diffusion layer and the center line extending in the width direction of the second storage node diffusion layer substantially match each other.

15. The semiconductor integrated circuit device according to claim 12, wherein the first storage node diffusion layer and the second storage node diffusion layer are formed such that the straight line passing through the first and second storage node diffusion layers and the length D of the crossing section between the first and second storage node diffusion layers satisfy relationship in the following (Expression 1); (where the short side of the first storage node diffusion layer+short side of the second storage node diffusion layer≦D≦(short side of the first storage node diffusion layer)½+(short side of the second storage node diffusion layer)½) (Expression 1).
